(19) United States
(12) Patent Application Publication
(10) Pub. No.: US 2013/0213804 A1
(43) Pub. Date: Aug. 22, 2013

(54) FERROMAGNETIC MATERIAL SPUTTERING TARGET

(71) Applicants: Atsutoshi Arakawa, Ibaraki (JP); Yuki Ikeda, Ibaraki (JP)

(72) Inventors: Atsutoshi Arakawa, Ibaraki (JP); Yuki Ikeda, Ibaraki (JP)

(73) Assignee: JX NIPPON MINING & METALS CORPORATION, Tokyo (JP)

(21) Appl. No.: 13/881,246

(22) PCT Filed: Dec. 15, 2011
(86) PCT No.: PCT/JP2011/079057

§ 371 Date: Apr. 24, 2013

(30) Foreign Application Priority Data
Dec. 17, 2010 (JP) 2010-281729

(51) Int. Cl. C23C 14/34

(52) U.S. Cl. CPC C23C 14/3407
USPC 204/298.13

(57) ABSTRACT

Provided is a ferromagnetic material sputtering target comprising a metal having a composition that Cr is contained in an amount of 20 mol % or less, Pt is contained in an amount of 5 mol % or more, and the remainder is Co, wherein the target includes a base metal (A) and, within the base metal (A), a Co—Pt alloy phase (B) containing 40 to 76 mol % of Pt, and a metal or alloy phase (C), which is different from the phase (B) and is composed of Co or an alloy comprising Co as a main component. The present invention improves the leakage magnetic flux to provide a ferromagnetic material sputtering target that can perform stable discharge with a magnetron sputtering apparatus.

### TECHNICAL FIELD

The present invention relates to a ferromagnetic material sputtering target that is used for forming a magnetic material thin film of a magnetic recording medium, in particular, a magnetic recording layer of a hard disk employing a perpendicular magnetic recording system, and relates to a nonmagnetic-grain-dispersed ferromagnetic material sputtering target that provides a large leakage magnetic flux and can provide stable electric discharge in sputtering with a magnetron sputtering apparatus.

### BACKGROUND ART

In the field of magnetic recording represented by hard disk drives, ferromagnetic metal materials, i.e., Co, Fe, or Ni-based materials are used as materials of magnetic thin films that perform recording. For example, in recording layers of hard disks employing a longitudinal magnetic recording system, Co—Cr or Co—Cr—Pt ferromagnetic alloys of which main component is Co are used.

In recording layers of hard disks employing a perpendicular magnetic recording system that has been recently applied to practical use, composite materials each composed of a Co—Cr—Pt ferromagnetic alloy of which main component is Co and a nonmagnetic inorganic material are widely used.

In many cases, the magnetic thin film of a magnetic recording medium such as a hard disk is produced by sputtering a ferromagnetic material sputtering target consisting primarily of the above-mentioned material because of its high productivity.

Such a ferromagnetic material sputtering target can be produced by a melting process or a powder metallurgical process. Though a process to be employed is decided depending on the requirement in characteristics, the sputtering target composed of a ferromagnetic alloy and nonmagnetic inorganic grains, which is used when forming a recording layer of a hard disk of a perpendicular magnetic recording system, is generally produced by a powder metallurgical process. This is because since inorganic grains need to be uniformly dispersed in a base alloy, it is difficult to produce the sputtering target by a melting process.

For example, proposed is a method of preparing a sputtering target for magnetic recording media by: mechanically alloying an alloy powder having an alloy phase, which was produced by rapid solidification, and a powder constituting a ceramic phase; uniformly dispersing the powder constituting a ceramic phase within the alloy powder; and molding it with a hot press (Patent Document 1).

The target structure in this case appears to be such that the base material is bound in a milt (cod roe) shape and surrounded with SiO₂ (ceramics) (FIG. 2 of Patent Document 1) or SiO₂ is dispersed in the form of strings in the base material (FIG. 3 of Patent Document 1). Though other drawings are unclear, they look as though they show similar structures.

Such a structure has problems described below and is not a preferred sputtering target for magnetic recording media. Note that the spherical substance shown in FIG. 4 of Patent Document 1 is not a structure constituting the target but a mechanically alloyed powder.

Without using an alloy powder produced by rapid solidification, a ferromagnetic material sputtering target also can be produced, by weighing commercially available raw material powders as the respective components constituting a target so as to achieve a desired composition, mixing the powders by a known process with, for example, a ball mill, and molding and sintering the powder mixture with a hot press.

For example, proposed is a method of preparing a sputtering target for magnetic recording media by mixing a powder mixture prepared by mixing a Co powder, a Cr powder, a TiO₂ powder, and a SiO₂ powder, with a Co spherical powder with a planetary-screw mixer, and molding the resulting powder mixture with a hot press (Patent Document 2).

The target structure in this case appears to be such that a metal phase (B) of spherical shape is present in a phase (A) as a base metal in which inorganic grains are uniformly dispersed (FIG. 1 of Patent Document 2). In such a structure, the leakage magnetic flux is not sufficiently increased in some cases depending on the content rate of the constituent elements such as Co and Cr. Thus, the target structure is not preferred as a sputtering target for magnetic recording media.

Furthermore, proposed is a method of preparing a sputtering target for forming thin films of magnetic recording medium by mixing a Co—Cr binary alloy powder, a Pt powder and a SiO₂ powder, and hot-pressing the resulting powder mixture (Patent Document 3).

It is described that the target structure in this case has a Pt phase, a SiO₂ phase and a Co—Cr binary alloy phase, and that a dispersion layer is observed in the periphery of the Co—Cr binary alloy layer (not shown in drawing). Such a structure is also not preferred as a sputtering target for magnetic recording media.

Patent Document 4 discloses a magnetron sputtering target including a magnetic phase containing Co, a nonmagnetic phase containing Co, and an oxide phase that are separated from one another. Though this technology aims to increase the amount of leakage magnetic flux, the phase structure thereof is different from that of the present invention described below and the functions and effects thereof are also different from those of the present invention. Accordingly, the Patent Document 4 cannot be used as a reference.

Patent Documents 5 and 6 each disclose a sputtering target for forming thin films of magnetic recording medium, which is composed of a nonmagnetic oxide, Cr, Pt, and the balance of Co. Though this technology aims to increase the amount of leakage magnetic flux, the phase structure thereof is different from that of the present invention described below and the functions and effects thereof are also different from those of the present invention. Accordingly, the Patent Documents 5 and 6 cannot be used as references.

Patent Documents 7 and 8 each disclose a method of producing a sputtering target for forming thin films of magnetic recording medium by pulverizing a sintered compact of primary raw material powder, mixing the resulting pulverized powder with a secondary raw material powder, and sintering the resulting mixture. Thus, Patent Documents 7 and 8 disclose inventions relating to processes of sintering and do not directly relate to the present invention described below.

There are sputtering apparatuses of various systems. In formation of the above-described magnetic recording films, magnetron sputtering apparatuses equipped with DC power sources are widely used because of their high productivity. Sputtering is a method of generating an electric field by applying a high voltage between a substrate serving as a positive electrode and a target serving as a negative electrode disposed so as to face each other under an inert gas atmosphere.

On this occasion, the inert gas is ionized into plasma composed of electrons and positive ions. The positive ions in the plasma collide with the surface of the target (negative electrode) to make the atoms constituting the target to eject from the target and to allow the ejected atoms to adhere to the facing substrate surface to form a film. Sputtering is based on the principle that a film of the material constituting a target is formed on a substrate by such series of actions. In a magnetic material target having unique component composition and phase structure, however, there is demand for a target that can perform stable discharge and efficient sputtering.

Patent Document 1: Japanese Laid-Open Patent Publication No. H10-88333

Patent Document 2: Japanese Patent Application No. 2010-011326

Patent Document 3: Japanese Laid-Open Patent Publication No. 2009-1860

Patent Document 4: Japanese Laid-Open Patent Publication No. 2010-255088

Patent Document 5: Japanese Laid-Open Patent Publication No. 2011-174174

Patent Document 6: Japanese Laid-Open Patent Publication No. 2011-175725

Patent Document 7: Japanese Laid-Open Patent Publication No. 2011-208169

Patent Document 8: Japanese Laid-Open Patent Publication No. 2011-42867

### SUMMARY OF INVENTION

### Technical Problem

In general, in sputtering of a ferromagnetic material sputtering target with a magnetron sputtering apparatus, most of the magnetic flux from a magnet passes through the inside of the target made of a ferromagnetic material to reduce the leakage magnetic flux, resulting in a big problem of no discharge or unstable discharge in sputtering.

In order to solve this problem, a reduction in content ratio of Co, which is a ferromagnetic metal, is suggested. A reduction in Co content, however, does not allow formation of a desired magnetic recording film and is therefore not an essential solution. Though it is possible to increase the leakage magnetic flux by reducing the thickness of the target, in this case, the target lifetime is shortened to require frequent replacement of the target, which causes an increase in the cost.

In view of the problems mentioned above, it is an object of the present invention to provide a nonmagnetic-grain-dispersed ferromagnetic material sputtering target of which the leakage magnetic flux is increased to allow stable discharge with a magnetron sputtering apparatus.

### Solution to Problem

In order to solve the above-mentioned problems, the present inventors have performed diligent studies and, as a result, have found that a target providing a large leakage magnetic flux can be obtained by regulating the composition and structural constitution of the target.

Accordingly, based on the findings, the present invention provides:

1) a ferromagnetic material sputtering target comprising a metal having a composition that Cr is contained in an amount of 20 mol % or less, Pt is contained in an amount of 5 mol % or more, and the remainder is Co, wherein the target includes a base metal (A) and, within the base metal (A), a Co—Pt alloy phase (B) containing 40 to 76 mol % of Pt, and a metal or alloy phase (C), which is different from the phase (B) and is composed of Co or an alloy comprising Co as a main component.

The present invention further provides:

2) the ferromagnetic material sputtering target according to 1) above, wherein the metal or alloy phase (C) contains 90 mol % or more of Co.

The present invention further provides:

3) the ferromagnetic material sputtering target according to 1) or 2) above, wherein 0.5 mol % or more and 10 mol % or less of at least one element selected from B, Ti, V, Mn, Zr, Nb, Ru, Mo, Ta, W, Si, and Al is contained as additive element.

The present invention further provides:

4) the ferromagnetic material sputtering target according to any one of 1) to 3) above, wherein the base metal (A) contains at least one inorganic material component selected from carbon, oxides, nitrides, carbides, and carbonitrides.

The present invention further provides:

5) the ferromagnetic material sputtering target according to any one of 1) to 4) above, wherein the inorganic material is at least one oxide of element selected from Cr, Ta, Si, Ti, Zr, Al, Nb, B, and Co, and the volume proportion of the nonmagnetic material is 20 to 40%.

The present invention further provides:

6) the ferromagnetic material sputtering target according to any one of 1) to 5) above, wherein the relative density is 97% or more.

### Advantageous Effects of Invention

The nonmagnetic-grain-dispersed ferromagnetic material sputtering target of the present invention, which was thus prepared, provides a large leakage magnetic flux to efficiently accelerate ionization of an inert gas to achieve stable discharge when the target is used in a magnetron sputtering apparatus. It is possible to increase the thickness of the target to enable a reduction in frequency of replacement of the target, resulting in an advantage that a magnetic material thin film can be produced with a low cost.

### DESCRIPTION OF EMBODIMENTS

The main component constituting a ferromagnetic material sputtering target of the present invention is a metal having a composition that Cr is contained in an amount of 20 mol % or less, Pt is contained in an amount of 5 mol % or more, and the remainder is Co.

Cr is an indispensable component, and the content is higher than 0 mol %. That is, the Cr content is higher than the analyzable lower limit. Furthermore, as long as the Cr content is 20 mol % or less, the effects can be obtained even if the amount of Cr is small.

The amount of Pt is desirably 45 mol % or less. An excessive amount of Pt decreases the characteristics as a magnetic material, and Pt is expensive. Accordingly, a smaller amount of Pt is desirable from the viewpoint of manufacturing cost.

The ferromagnetic material sputtering target can further contain 0.5 mol % or more and 10 mol % or less of at least one element selected from B, Ti, V, Mn, Zr, Nb, Ru, Mo, Ta, W, Si, and Al as additive element. These elements are optionally added to the target material for improving the characteristics of a magnetic recording medium. The blending ratios can be variously adjusted within the above-mentioned ranges, while maintaining the characteristics as an effective magnetic recording medium.

The 0.5 mol % or more and 10 mol % or less of at least one element selected from B, Ti, V, Mn, Zr, Nb, Ru, Mo, Ta, W, Si, and Al as additive element is basically present in the base metal (A), but may slightly disperse into the Co-Pt alloy phase (B) described below through the interface with the phase (B). The present invention also entails such a case.

Similarly, the 0.5 mol % or more and 10 mol % or less of at least one element selected from B, Ti, V, Mn, Zr, Nb, Ru, Mo, Ta, W, Si, and Al as additive element is basically present in the base metal (A), but may slightly disperse into the metal or alloy phase (C) composed of Co or an alloy comprising Co as a main component described below through the interface with the phase (C). The present invention also entails such a case.

Furthermore, the metal or alloy phase (C) may contain 90 mol % or more of Co, and further includes a case of Co alloy with at least one element selected from B, Ti, V, Mn, Zr, Nb, Ru, Mo, Ta, W, Si, and Al as additive element.

An important point of the present invention is that the structure of the target includes a base metal (A) and, within the base metal (A), a Co—Pt alloy phase (B) containing 40 to 76 mol % of Pt and a metal or alloy phase (C) composed of Co or the Co alloy. The phase (B) has a maximum magnetic permeability lower than that of the structure surrounding the phase, and the phases are separated from each other by the base metal (A). The phase (C) has a maximum magnetic permeability higher than that of the structure surrounding the phase, and the phases are separated from each other by the base metal (A).

The effect of improving the leakage magnetic flux is expressed even in a target structure composed of a base metal (A) and a Co—Pt alloy phase (B) containing 40 to 76 mol % of Pt, or composed of a base metal (A) and a metal or alloy phase (C), which is composed of Co or an alloy comprising Co as a main component; but the effect of improving the leakage magnetic flux is further enhanced in a target in which the base metal (A), the alloy phase (B), and the alloy phase (C) are present.

In the target having such a structure, though the reasons of the improvement in leakage magnetic flux are not necessarily obvious at the present moment, it is believed that a portion with high magnetic flux density and a portion with low magnetic flux density are generated inside the target to cause an increase in magnetostatic energy compared with the structure having a uniform magnetic permeability and thereby leakage of the magnetic flux to the outside of the target may become energetically advantageous.

The phase (B) desirably has a diameter of 10 to 150 μm. In the base metal (A), the phase (B) and fine inorganic grains are present. If the diameter of the phase (B) is smaller than 10 μm, the difference in size with the inorganic grains is small, and therefore, it accelerates diffusion between the phase (B) and the base metal (A) during sintering of the target material.

The progress of the diffusion makes the difference in structural component between the base metal (A) and the phase (B) unclear. Accordingly, the diameter of the phase (B) is preferably 10 μm or more, and more preferably 30 μm or more.

If the diameter exceeds 150 μm, the smoothness of the target surface decreases with the progress of sputtering. This may cause a problem of particles. Accordingly, the diameter of the phase (B) is desirably 150 μm or less.

All of these are means for increasing the leakage magnetic flux. The leakage magnetic flux also can be controlled by the amounts and types of additive metals and inorganic grains. Accordingly, the above-described size of the phase (B) does not necessarily have to be satisfied, but is one of favorable conditions.

Even if the proportion of the phase (B) to the total volume of the target or to the volume or area of the erosion surface of the target is small (e.g., about 1%), the effect of a certain level can be obtained.

In order to sufficiently obtain the effect by the presence of the phase (B), however, the proportion of the phase (B) to the total volume of the target or to the volume or area of the erosion surface of the target is desirably 10% or more. The leakage magnetic flux can be increased by the presence of many phases (B).

In some target compositions, the proportion of the phase (B) to the total volume of the target or to the volume or area of the erosion surface of the target can be 50% or more, or further 60% or more. The volume or area proportion can be appropriately adjusted depending on the composition of the target. The present invention also entails such cases.

Incidentally, the phase (B) in the present invention may have any shape, and the average grain size means the average between the minimum diameter and the maximum diameter.

The composition of the phase (B) is different from that of the base metal (A). Therefore, the composition in the periphery of the phase (B) may slightly change from that of the phase (B) by diffusion of elements during sintering.

In the range of a phase having a shape similar to that of the phase (B) and having diameters (major axis and minor axis) each reduced to two-thirds of the phase (B), the purpose can be achieved as long as the phase (B) is made of a Co—Pt alloy containing 40 to 76 mol % of Pt. The present invention entails such a case, and the purpose of the present invention can be achieved under such conditions.

The phase (C) desirably has a diameter of 30 to 150 μm. If the diameter of the phase (C) is smaller than 30 μm, the difference in grain size with the metal grains coexisting with the inorganic grains is small, and therefore, it accelerates diffusion between the phase (C) and the base metal (A) during sintering of the target material. Thus, the difference in structural component between the base metal (A) and the phase (C) tends to become unclear. Accordingly, the diameter of the phase (C) is preferably 30 μm or more, and more preferably 40 μm or more.

If the diameter exceeds 150 μm, the smoothness of the target surface decreases with the progress of sputtering. This may cause a problem of particles. Accordingly, the size of the phase (C) is desirably 30 to 150 μm.

All of these are means for increasing the leakage magnetic flux. The leakage magnetic flux also can be controlled by the amounts and types of additive metals and inorganic grains. Accordingly, the above-described size of the phase (C) does not necessarily have to be satisfied, but is one of favorable conditions.

In order to sufficiently obtain the effect by the presence of the phase (C), however, the proportion of the phase (C) to the total volume of the target or to the volume or area of the erosion surface of the target is desirably 10% or more. The leakage magnetic flux can be increased by the presence of many phases (C).

In some target compositions, the proportion of the phase (C) to the total volume of the target or to the volume or area of the erosion surface of the target can be 50% or more, or further 60% or more. The volume or area proportion can be appropriately adjusted depending on the composition of the target. The present invention also entails such cases.

Incidentally, the phase (C) in the present invention may have any shape, and the average grain size means the average of the minimum diameter and the maximum diameter.

The composition of the phase (C) is different from that of the base metal (A). Therefore, the composition in the periphery of the phase (C) may slightly change from that of the phase (C) by diffusion of elements during sintering.

In the range of a phase having a shape similar to that of the phase (C) and having diameters (major axis and minor axis) each reduced to two-thirds of the phase (C), the purpose can be achieved as long as the metal or alloy phase (C) is composed of Co or an alloy comprising Co as a main component. The present invention entails such a case, and the purpose of the present invention can be achieved under such conditions.

Furthermore, the ferromagnetic material sputtering target of the present invention may contain at least one inorganic material, which is dispersed in the base metal, selected from carbon, oxides, nitrides, carbides, and carbonitrides. In such a case, the target has characteristics suitable as a material for a magnetic recording film having a granular structure, in particular, a recording film for a hard disk drive employing a perpendicular magnetic recording system.

Furthermore, as the inorganic material, at least one oxide of element selected from Cr, Ta, Si, Ti, Zr, Al, Nb, B, and Co is effective. The volume proportion of the nonmagnetic material can be 20 to 40%. In the case of an oxide of Cr, the amount of Cr oxide is distinguished from the amount of Cr added as a metal and is determined as a volume proportion as a chromium oxide.

The nonmagnetic grains are usually dispersed in the base metal (A), but some of them may adhere to the circumference of the phase (B) or the phase (C) or become incorporated into the phase (B) or the phase (C) during production of a target. If the amount is small, the nonmagnetic grains in such a case do not affect the magnetic characteristics of the phase (B) or the phase (C) and do not inhibit the purpose.

The ferromagnetic material sputtering target of the present invention more desirably has a relative density of 97% or more. It is generally known that a target having a higher density can more effectively reduce the particles generated during sputtering. Also in the present invention, a higher density is preferred. In the present invention, a relative density of 97% or more can be achieved.

The relative density in the present invention is a value determined by dividing the measured density of a target by the calculated density (theoretical density). The calculated density is a density assuming the structural components of a target coexist without diffusing to or reacting with each other, and is calculated by the following expression:

Expression: calculated density=Σ[(molecular weight of a structural component)×(molar ratio of the structural component)]/Σ[(molecular weight of the structural component)×(molar ratio of the structural component)/(literature density of the structural component)], wherein E is the sum of the values of all structural components of the target.

The thus prepared target provides a large leakage magnetic flux. When the target is used in a magnetron sputtering apparatus, ionization of an inert gas is efficiently accelerated to achieve stable discharge. It is possible to increase the thickness of the target to enable a reduction in frequency of replacement of the target, resulting in an advantage that a magnetic material thin film can be produced with a low cost.

Furthermore, the increase in density has an advantage of reducing the particle generation that causes a reduction in yield.

The ferromagnetic material sputtering target of the present invention can be produced by a powder metallurgy process. First, a powder of a metal element or alloy (note that a Co—Pt alloy powder is indispensable for forming the phase (B)) and, as necessary, a powder of an additive metal element are prepared. Though each metal element powder may be produced by any method, the maximum grain sizes of these powders are each desirably 20 μm or less.

Furthermore, instead of each metal element powder, an alloy powder of these metals may be prepared. In also such a case, though the powder may be produced by any method, the maximum grain size of the powder is desirably 20 μm or less. A too small grain size, however, accelerates oxidation to cause problems such as a deviation of the component composition from the necessary range. Accordingly, the size is further desirably 0.1 μm or more.

Subsequently, the metal powder and the alloy powder are weighed to achieve a desirable composition and are mixed and pulverized with a known procedure using, for example, a ball mill. When an inorganic material powder is also added, the powder may be mixed with the metal powder and the alloy powder in this stage.

As the inorganic material powder, a carbon powder, an oxide powder, a nitride powder, a carbide powder, or a carbonitride powder is prepared. The inorganic material powder desirably has a maximum grain size of 5 μm or less, whereas a too small grain size tends to cause agglomeration. Accordingly, the size is further desirably 0.1 μm or more.

The Co—Pt powder can be prepared by gas atomization and sieving of the product. A Co powder having a diameter in the range of 30 to 150 μm also can be prepared by gas atomization and sieving of the product. The thus prepared Co—Pt powder and pure Co powder each having a diameter in the range of 30 to 150 μm, a metal powder prepared in advance, and an optionally selected inorganic material powder are mixed with a mixer. The mixer is preferably a planetary-screw mixer or planetary-screw mixing agitator. In addition, considering the problem of oxidation during mixing, the mixing is preferably performed in an inert gas atmosphere or in vacuum.

The thus prepared powder is molded and sintered with a vacuum hot press apparatus, followed by machining into a desired shape to provide a ferromagnetic material sputtering target of the present invention.

The molding and sintering is not limited to hot pressing and may be performed by spark plasma sintering or hot hydrostatic pressing. The retention temperature for the sintering is preferably set to the lowest temperature in the temperature range in which the target is sufficiently densified. Though it depends on the composition of a target, in many cases, the temperature is in the range of 800 to 1300° C. The pressure in the sintering is preferably 300 to 500 kg/cm².

### EXAMPLES

The present invention will now be described by Examples and Comparative Examples. The Examples are merely illustrative, and the present invention shall in no way be limited thereby. In other words, the present invention shall only be limited by the scope of claim for a patent, and shall include various modifications other than the Examples of this invention.

### Example 1 and Comparative Examples 1 and 2

In Example 1, a Co powder having an average grain size of 3 μm, a Cr powder having an average grain size of 6 μm, a Pt powder having an average grain size of 3 μm, a CoO powder having an average grain size of 2 μm, a SiO₂ powder having an average grain size of 1 μm, a Co-50Pt (mol %) powder having a diameter in the range of 50 to 150 μm, and a Co powder having a diameter in the range of 70 to 150 μm were prepared as raw material powders.

These powders were weighed at weight proportions of 16.93 wt % of the Co powder, 2.95 wt % of the Cr powder, 16.62 wt % of the Pt powder, 4.84 wt % of the CoO powder, 5.43 wt % of the SiO₂ powder, 33.23 wt % of the Co—Pt powder, and 20.0 wt % of the Co powder having a diameter in the range of 70 to 150 μm to obtain a target having a composition of 88(Co-5Cr-15Pt)-5CoO-7SiO₂ (mol %).

Subsequently, the Co powder, the Cr powder, the Pt powder, the CoO powder, the SiO₂ powder, and the Co powder having a diameter in the range of 70 to 150 μm were placed in a 10-liter ball mill pot together with zirconia balls as a pulverizing medium, and the mill pot was rotated for 20 hours for mixing. The resulting powder mixture was further mixed with the Co—Pt powder with a planetary-screw mixer having a ball capacity of about 7 liters for 10 minutes.

The resulting powder mixture was charged in a carbon mold and was hot-pressed in a vacuum atmosphere under conditions of a temperature of 1100° C., a retention time of 2 hours, and a pressure of 30 MPa to obtain a sintered compact. The sintered compact was then ground with a surface grinder to obtain a disk-shaped target having a diameter of 180 mm and a thickness of 5 mm.

The leakage magnetic flux was measured based on ASTM F2086-01 (Standard Test Method for Pass Through Flux of Circular Magnetic Sputtering Targets, Method 2). The target was fixed at the center thereof and was rotated by 0, 30, 60, 90, and 120 degrees, and the leakage magnetic flux density (PTF) of the target was measured at each degree of rotation and was divided by the reference field value defined in ASTM and multiplied by 100 to obtain a percentage value. The average of the values at the five points is shown in Table 1 as the average leakage magnetic flux density (PTF (%)).

In Comparative Example 1, a Co powder having an average grain size of 3 μm, a Cr powder having an average grain size of 6 μm, a Pt powder having an average grain size of 3 μm, a CoO powder having an average grain size of 2 μm, and a SiO₂ powder having an average grain size of 1 μm were prepared as raw material powders. These powders were weighed at weight proportions of 53.55 wt % of the Co powder, 2.95 wt % of the Cr powder, 33.24 wt % of the Pt powder, 4.84 wt % of the CoO powder, and 5.43 wt % of the SiO₂ powder to obtain a target having a composition of 88(Co-5Cr-15Pt)-5CoO-7SiO₂ (mol %).

These powders were placed in a 10-liter ball mill pot together with zirconia balls as a pulverizing medium, and the mill pot was rotated for 20 hours for mixing.

Subsequently, the resulting powder mixture was charged in a carbon mold and was hot-pressed in a vacuum atmosphere under conditions of a temperature of 1100° C., a retention time of 2 hours, and a pressure of 30 MPa to obtain a sintered compact. The sintered compact was then ground with a surface grinder to obtain a disk-shaped target having a diameter of 180 mm and a thickness of 5 mm. The average leakage magnetic flux density (PTF) of the target was measured.

In Comparative Example 2, a Co powder having an average grain size of 3 μm, a Cr powder having an average grain size of 6 μm, a CoO powder having an average grain size of 2 μm, a SiO₂ powder having an average grain size of 1 μm, a Co-81Pt (mol %) powder having a diameter in the range of 50 to 150 μm, and a Co powder having a diameter in the range of 70 to 150 μm were prepared as raw material powders.

These powders were weighed at weight proportions of 25.75 wt % of the Co powder, 2.95 wt % of the Cr powder, 4.84 wt % of the CoO powder, 5.43 wt % of the SiO₂ powder, 41.03 wt % of the Co—Pt powder, and 20.0 wt % of the Co powder having a diameter in the range of 70 to 150 μm to obtain a target having a composition of 88(Co-5Cr-15Pt)-5CoO-7SiO₂ (mol %).

Subsequently, the Co powder, the Cr powder, the CoO powder, the SiO₂ powder, and the Co powder having a diameter in the range of 70 to 150 μm were placed in a 10-liter ball mill pot together with zirconia balls as a pulverizing medium, and the mill pot was rotated for 20 hours for mixing. The resulting powder mixture was further mixed with the Co—Pt powder with a planetary-screw mixer having a ball capacity of about 7 liters for 10 minutes.

The resulting powder mixture was charged in a carbon mold and was hot-pressed in a vacuum atmosphere under conditions of a temperature of 1100° C., a retention time of 2 hours, and a pressure of 30 MPa to obtain a sintered compact. The sintered compact was ground with a surface grinder to obtain a disk-shaped target having a diameter of 180 mm and a thickness of 5 mm. The results of the above are collectively shown in Table 1.

TABLE 1

| | | | | | Relative |
|---|---|---|---|---|---|
| No. | Target composition (mol %) | Phase (B) | Phase (C) | PTF(%) | density(%) |
| Example 1 | 88(Co—5Cr—15Pt)—5CoO—7SiO₂ | Grain size: 50 to 150 | Grain size: 70 to 150 | 44.2 | 97.4 |
| | | μm; Co—50 mol % Pt | μm; Pure Co | | |
| Comparative | 88(Co—5Cr—15Pt)—5CoO—7SiO₂ | None | None | 38.1 | 97.0 |
| Example 1 | | | | | |
| Comparative | 88(Co—5Cr—15Pt)—5CoO—7SiO₂ | Grain size: 50 to 150 | Grain size: 70 to 150 | 40.8 | 97.2 |
| Example 2 | | μm; Co—81 mol % Pt | μm; Pure Co | | |

As shown in Table 1, the average leakage magnetic flux density (PTF) of the target of Example 1 was 44.2%, which was larger than, 38.1% and 40.8% of Comparative Examples 1 and 2, respectively, and was confirmed to be considerably improved. In Example 1, the relative density was 97.4%. Thus, a target having a high density exceeding 97% was obtained.

### Example 2 and Comparative Example 3

In Example 2, a Co powder having an average grain size of 3 μm, a Cr powder having an average grain size of 6 μm, a Pt powder having an average grain size of 3 μm, a Ru powder having an average grain size of 5 μm, a TiO₂ powder having an average grain size of 1 μm, a SiO₂ powder having an average grain size of 1 μm, a Cr₂O₃ powder having an average grain size of 3 μm, a Co-50Pt (mol %) powder having a diameter in the range of 50 to 150 μm, and a Co powder having a diameter in the range of 70 to 150 μm were prepared as raw material powders.

These powders were weighed at weight proportions of 18.86 wt % of the Co powder, 3.44 wt % of the Cr powder, 21.53 wt % of the Pt powder, 5.58 wt % of the Ru powder, 3.53 wt % of the TiO₂ powder, 2.65 wt % of the SiO₂ powder, 3.36 wt % of the Cr₂O₃ powder, 28.04 wt % of the Co—Pt powder, and 13.01 wt % of the Co powder having a diameter in the range of 70 to 150 μm to obtain a target having a composition of 59Co-6Cr-20Pt-5Ru-4TiO₂-4SiO₂-2Cr₂O₃ (mol %).

Subsequently, the Co powder, the Cr powder, the Pt powder, the Ru powder, the TiO₂ powder, the SiO₂ powder, the Cr₂O₃ powder, and the Co powder having a diameter in the range of 70 to 150 μm were placed in a 10-liter ball mill pot together with zirconia balls as a pulverizing medium, and the mill pot was rotated for 20 hours for mixing. The resulting powder mixture was further mixed with the Co—Pt powder with a planetary-screw mixer having a ball capacity of about 7 liters for 10 minutes.

The resulting powder mixture was charged in a carbon mold and was hot-pressed in a vacuum atmosphere under conditions of a temperature of 1100° C., a retention time of 2 hours, and a pressure of 30 MPa to obtain a sintered compact. The sintered compact was ground with a surface grinder to obtain a disk-shaped target having a diameter of 180 mm and a thickness of 5 mm. The average leakage magnetic flux density (PTF) of the target was measured.

In Comparative Example 3, a Co powder having an average grain size of 3 μm, a Cr powder having an average grain size of 6 μm, a Pt powder having an average grain size of 3 μm, a Ru powder having an average grain size of 5 μm, a TiO₂ powder having an average grain size of 1 μm, a SiO₂ powder having an average grain size of 1 μm, and a Cr₂O₃ powder having an average grain size of 3 μm were prepared as raw material powders. These powders were weighed at weight proportions of 38.38 wt % of the Co powder, 3.44 wt % of the Cr powder, 43.06 wt % of the Pt powder, 5.58 wt % of the Ru powder, 3.53 wt % of the TiO₂ powder, 2.65 wt % of the SiO₂ powder, and 3.36 wt % of the Cr₂O₃ powder to obtain a target having a composition of 59Co-6Cr-20Pt-5Ru-4TiO₂-4SiO₂-2Cr₂O₃ (mol %).

These powders were placed in a 10-liter ball mill pot together with zirconia balls as a pulverizing medium, and the mill pot was rotated for 20 hours for mixing.

Subsequently, the resulting powder mixture was charged in a carbon mold and was hot-pressed in a vacuum atmosphere under conditions of a temperature of 1100° C., a retention time of 2 hours, and a pressure of 30 MPa to obtain a sintered compact. The sintered compact was ground with a surface grinder to obtain a disk-shaped target having a diameter of 180 mm and a thickness of 5 mm. The average leakage magnetic flux density (PTF) of the target was measured. The results of the above are collectively shown in Table 2.

TABLE 2

| | | | | | Relative |
|---|---|---|---|---|---|
| No. | Target composition (mol %) | Phase (B) | Phase (C) | PTF(%) | density(%) |
| Example 2 | 59Co—6Cr—20Pt—5Ru—4TiO₂—4SiO₂—2Cr₂O₃ | Grain size: 50 to 150 | Grain size: 70 to 150 | 46.7 | 98.2 |
| | | μm; Co—50 mol % Pt | μm; Pure Co | | |
| Comparative | 59Co—6Cr—20Pt—5Ru—4TiO₂—4SiO2—2Cr₂O₃ | None | None | 39.2 | 98.0 |
| Example 3 | | | | | |

As shown in Table 2, the average leakage magnetic flux density (PTF) of the target of Example 2 was 46.7%, which was larger than 39.2% of Comparative Example 2, and was confirmed to be considerably improved. In addition, the relative density of Example 2 was 98.2%. Thus, a target having a high density exceeding 97% was obtained.

The above-described Examples show an example of a target having a composition of 88(Co-5Cr-15Pt)-5CoO-7SiO₂ (mol %) and an example of a target having a composition of 59Co-6Cr-20Pt-5Ru-4TiO₂-4SiO₂-2Cr₂O₃ (mol %). It was confirmed that similar effects can be obtained even if the composition ratio is changed within the range of the present invention.

In the above-described Examples, Ru alone is added; however, the target may contain at least one element selected from B, Ti, V, Mn, Zr, Nb, Ru, Mo, Ta, W, Si, and Al as additive element, and all of such targets can maintain the characteristics as effective magnetic recording media. In other words, these elements are optionally added to target material for improving the characteristics of magnetic recording media. Though the effects in each case are not specially shown in Examples, it was confirmed that the effects were equivalent to those shown in Examples of the present invention.

Furthermore, though the above-described Examples show cases of adding oxide of Si, Ti, or Cr, other oxides of Ta, Zr, Al, Nb, B, or Co show equivalent effects. In addition, though the above describes the cases of adding oxides, it was confirmed that nitrides, carbides, carbonitrides and carbon of these elements can show effects equivalent to those of oxides.

### INDUSTRIAL APPLICABILITY

The present invention can notably improve the leakage magnetic flux by regulating the structural constitution of a ferromagnetic material sputtering target. Accordingly, the use of a target of the present invention can give stable discharge in sputtering with a magnetron sputtering apparatus. Furthermore, it is possible to increase the thickness of a target, and thereby increase the target lifetime to allow production of a magnetic material thin film at a low cost.

The target of the present invention is useful as a ferromagnetic material sputtering target that is used for forming a magnetic material thin film of a magnetic recording medium, in particular, forming a recording layer of a hard disk drive.

1. A ferromagnetic material sputtering target comprising a metal having a composition that Cr is contained in an amount of 20 mol % or less, Pt is contained in an amount of 5 mol % or more, and the remainder is Co, wherein the target includes a base metal (A) and, within the base metal (A), a Co—Pt alloy phase (B) containing 40 to 76 mol % of Pt, and a metal or alloy phase (C), which is different from the phase (B) and is composed of Co or an alloy comprising Co as a main component.

2. The ferromagnetic material sputtering target according to claim 1, wherein the metal or alloy phase (C) contains 90 mol % or more of Co.

3. A ferromagnetic material sputtering target comprising a metal having a composition that Cr is contained in an amount of 20 mol % or less, Pt is contained in an amount of 5 mol % or more, at least one element selected from the group consisting of B, Ti, V, Mn, Zr, Nb, Mo, Ta, W, Si, and Al is contained as additive element in an amount of 0.5 mol % or more and 10 mol % or less, and the remainder is Co, wherein the target includes a base metal (A) and, within the base metal (A), a Co—Pt alloy phase (B) containing 40 to 76 mol % of Pt, and a metal or alloy phase (C), which is different from the phase (B) and is composed of Co or an alloy comprising Co as a main component.

4. The ferromagnetic material sputtering target according to claim 3, wherein the base metal (A) contains at least one inorganic material component selected from the group consisting of carbon, oxides, nitrides, carbides, and carbonitrides.

5. The ferromagnetic material sputtering target according to claim 4, wherein the inorganic material is at least one oxide of an element selected from the group consisting of Cr, Ta, Si, Ti, Zr, Al, Nb, B, and Co, and the volume proportion of nonmagnetic material composed of the inorganic material is 20 to 40%.

6. The ferromagnetic material sputtering target according To claim 5, wherein the sputtering target has a relative density is of 97% or more.

7. The ferromagnetic material sputtering target according to claim 6, wherein the metal or alloy phase (C) contains 90 mol % or more of Co.

8. The ferromagnetic material sputtering target according to claim 3, wherein the metal or alloy phase (C) contains 90 mol % or more of Co.

9. The ferromagnetic material sputtering target according to claim 2, wherein the base metal (A) contains at least one inorganic material component selected from the group consisting of carbon, oxides, nitrides, carbides, and carbonitrides.

10. The ferromagnetic material sputtering target according to claim 9, wherein the inorganic material is at least one oxide of an element selected from the group consisting of Cr, Ta, Si, Ti, Zr, Al, Nb, B, and Co, and the volume proportion of nonmagnetic material composed of the inorganic material is 20 to 40%.

11. The ferromagnetic material sputtering target according to claim 10, wherein the sputtering target has a relative density of 97% or more.

12. The ferromagnetic material sputtering target according to claim 1, wherein the base metal (A) contains at least one inorganic material component selected from the group consisting of carbon, oxides, nitrides, carbides, and carbonitrides.

13. The ferromagnetic material sputtering target according to claim 12, wherein the inorganic material is at least one oxide of an element selected from the group consisting of Cr, Ta, Si, Ti, Zr, Al, Nb, B, and Co, and the volume proportion of nonmagnetic material composed of the inorganic material is 20 to 40%.

14. The ferromagnetic material sputtering target according to claim 1, wherein the sputtering target has a relative density of 97% or more.
